(19) United States
(12) Patent Application Publication
(10) Pub. No.: US 2026/0055509 A1
(43) Pub. Date: Feb. 26, 2026

(54) BATCH-TYPE SUBSTRATE-PROCESSING APPARATUS

(71) Applicant: EUGENE TECHNOLOGY CO., LTD., Yongin-si, Gyeonggi-do (KR)

(72) Inventors: Chang Dol KIM, Yongin-si, Gyeonggi-do (KR); Sung Min NAM, Yongin-si, Gyeonggi-do (KR); Seung Hyun YOON, Yongin-si, Gyeonggi-do (KR)

(21) Appl. No.: 19/103,548

(22) PCT Filed: Aug. 28, 2023
(86) PCT No.: PCT/KR2023/012733

§ 371 Date: Feb. 12, 2025

(30) Foreign Application Priority Data
Aug. 31, 2022 (KR) 10-2022-0109736

(51) Int. Cl. C23C 16/52; C23C 16/44; C23C 16/455

(52) U.S. Cl. CPC C23C 16/52; C23C 16/4409; C23C 16/4557

(57) ABSTRACT

The present inventive concept relates to a batch-type substrate-processing apparatus for preventing powder formation caused by condensation of process gas on the inner circumferential surface of a gas inlet port, the batch-type substrate-processing apparatus comprising: a reaction tube for providing a processing space in which a plurality of substrates are accommodated; a ring-shaped flange part which has a fluid passage provided therein and supports the reaction tube; a first sealing member provided between the reaction tube and the flange part; a refrigerant-supply part for supplying a refrigerant to the fluid passage; a gas-supply pipe for supplying process gas to the processing space through the flange part; a gas inlet port coupled to the outer end of the gas-supply pipe; and a heater part for heating the gas inlet port.

### TECHNICAL FIELD

The present inventive concept relates to a batch-type substrate-processing apparatus, and more particularly, to a batch-type substrate-processing apparatus that prevents powder from being accumulated by condensation of a process gas on an inner circumferential surface of a gas inlet port.

### BACKGROUND ART

In general, a substrate processing apparatus is an apparatus in which a substrate to be processed within a processing space is disposed to deposit reactive particles contained in the process gas injected into the processing space using a chemical vapor deposition (CVD) method or an atomic layer deposition (ALD) method. There are a single wafer type that is capable of performing a processing process on one substrate and a batch-type that is capable of performing a processing process a plurality of substrates at the same time.

The batch-type substrate-processing apparatus may include a vertical reaction tube, a flange part supporting the reaction tube, and a sealing member interposed between the reaction tube and the flange part to seal a space between the reaction tube and the flange part.

Here, since the sealing member may be deformed and/or damaged due to a high process temperature, a fluid passage may be formed in the flange part to allow a refrigerant to flow so as not to be deformed and/or damaged due to the high temperature.

Here, a gas-supply pipe that supplies the process gas to the processing space of the reaction tube by passing through the flange part and/or a gas inlet port connected to an outer end of the gas-supply pipe may be thermally connected (e.g., in contact with) to the flange part to cause a heat loss. In this case, the process gas inside the gas-supply pipe and/or gas inlet port is condensed to generate powder and then accumulated on an inner surface of the gas-supply pipe and/or gas inlet port. Particularly, the sealing member and the process gas, which are cooled by the refrigerant flowing through the fluid passage of the flange part, may be in direct contact with each other, and thus, the powder may be intensively accumulated. The powder accumulated in this manner becomes a main source of particles to cause serious problems by being supplied into to the processing space together with the process gas, thereby deteriorating quality of a thin film.

Therefore, a configuration capable of preventing and/or suppressing the powder from being accumulated on the inner circumferential surfaces of the gas-supply pipe and the gas inlet port and the coupled portion of the gas-supply pipe and the gas inlet port is required.

(Patent Document 1) Korean Patent Publication No. 10-2007-0072777

### DISCLOSURE OF THE INVENTIVE CONCEPT

### Technical Problem

The present inventive concept provides a batch-type substrate-processing apparatus having a heater part that heats a gas inlet port coupled to an outer end of a gas-supply pipe that supplies a process gas through a flange part, in which a fluid passage of a refrigerant is formed.

### Technical Solution

A batch-type substrate-processing apparatus according to an embodiment of the present inventive concept may include: a reaction tube configured to provide a processing space in which a plurality of substrates are accommodated; a ring-shaped flange part provided with a fluid passage and configured to support the reaction tube; a first sealing member provided between the reaction tube and the flange part; a refrigerant-supply part configured to supply a refrigerant to the fluid passage; a gas-supply pipe configured to supply a process gas to the processing space through the flange part; a gas inlet port coupled to an outer end of the gas-supply pipe; and a heater part configured to heat the gas inlet port.

The heater part may include: a line heater extending along a circumferential direction of the flange part; and a metal block embedded in the line heater and provided to surround the gas inlet port.

The metal block may include: an upper block configured to cover an upper portion of the gas inlet port; and a lower block configured to cover a lower portion of the gas inlet port.

The line heater may include: an upper heater provided in the upper block; and a lower heater provided in the lower block, wherein the upper block and the lower block may include heater insertion grooves into which the upper heater and the lower heater are inserted, respectively, and the metal block further comprises an upper block cover and a lower block cover, which are configured to cover the heater insertion grooves of the upper block and the lower block, respectively.

The batch-type substrate-processing apparatus may further include: a temperature detection part configured to detect a temperature of the heater part; and a heating control part configured to control a heating temperature of the heater part according to the temperature detected by the temperature detection part.

The gas-supply pipe may be provided in plurality and pass through the flange part in a radial direction, wherein the plurality of gas-supply pipes may be disposed along a circumferential direction of the flange part, and a length of the line heater may be proportional to the number of gas-supply pipes.

The temperature detection part may include: a first temperature measurement member provided at a central portion of the heater part in an extension direction of the line heater; and a second temperature measurement member spaced apart from the first temperature measurement member in the extension direction of the line heater and provided at an edge portion of the heater part in the extension direction of the line heater.

The heating control part may be configured to: control the heating temperature of the heater part based on a first temperature of the heater part, which is measured from the first temperature measurement member; and control the heating temperature of the heater part by reflecting a second temperature of the heater part according to a difference between the first temperature of the heater part and the second temperature of the heater part, which is measured from the second temperature measurement member.

The heating control part may be configured to reflect the second temperature of the heater part when the difference between the first temperature of the heater part and the second temperature of the heater part is greater than an allowable value.

An interval between the first temperature measurement member and the second temperature measurement member may be greater than that between the plurality of gas-supply pipes.

The gas-supply pipe may pass through the reaction tube in a radial direction, and the batch-type substrate-processing apparatus may further include: a second sealing member provided between the reaction tube and the gas-supply pipe; and a third sealing member provided between the gas-supply pipe and the gas inlet port.

The flange part may be provided outside a lower end of the reaction tube, the gas-supply pipe may further pass through the flange part in the radial direction, the second sealing member may be disposed between the reaction tube and the flange part, the third sealing member may be disposed between the gas-supply pipe and the flange part, and the heater part may be provided outside the flange part.

An inner diameter of the gas inlet port may be less than an inner diameter of the gas-supply pipe.

### Advantageous Effects

In the batch-type substrate-processing apparatus according to the embodiment of the present inventive concept, the fluid passage may be provided in the flange part to prevent the thermal deformation and/or damage of the first sealing member provided between the reaction tube and the flange part, thereby heating the gas inlet port through the heater part while the refrigerant flows, and thus, the powder may be prevented and/or suppressed from being accumulated at the inner circumferential surfaces of the gas-supply pipe and the gas inlet port and the coupled portion of the gas-supply pipe and the gas inlet port due to the concentration of the process gas.

Here, the heater part may be constituted by the line heater extending along the circumferential direction of the flange part and the metal block, in which the line heater is built, to maintain an internal temperature of each of the gas inlet port and/or the gas-supply pipe to a temperature (e.g., 150° C. or more) at which the process gas is not condensed. In addition, even when the gas-supply pipe is provided as a plurality of parts, the heater part nay be provided in proportion to the number of gas-supply pipes, and the internal temperature of each gas-supply pipe and the gas inlet port may be uniformly maintained to a temperature at which the process gas is not condensed through the heater part (or line heater) extending along a circumferential direction of the flange part.

Here, the temperature of the heater part is detected through a temperature detection part, and a heating temperature of the heater part is controlled to control the gas inlet port to a desired temperature. In addition, the temperature detection part may be constituted by the first temperature measurement member provided at the central portion in the extension direction of the line heater of the heater part and the second temperature measurement member provided at the edge portion in the extension direction of the line heater to control the plurality of gas inlet ports to the uniform temperature by reflecting the second temperature of the heater part according to the difference between the second temperature of the heater part, which is measured from the second temperature measurement member, and the first temperature of the heater part while controlling the heating temperature of the heater part on the basis of the first temperature of the heater part, which is measured from the first temperature measurement member.

### BRIEF DESCRIPTION OF THE DRAWINGS

FIG. 1 is a schematic perspective view of a batch-type substrate-processing apparatus according to an embodiment of the present inventive concept.

FIG. 2 is an exploded perspective view of a heater part according to an embodiment of the present inventive concept.

FIG. 3 is a conceptual view for explaining a coupling structure of a gas inlet port and the heater part according to an embodiment of the present inventive concept.

### MODE FOR CARRYING OUT THE INVENTIVE CONCEPT

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

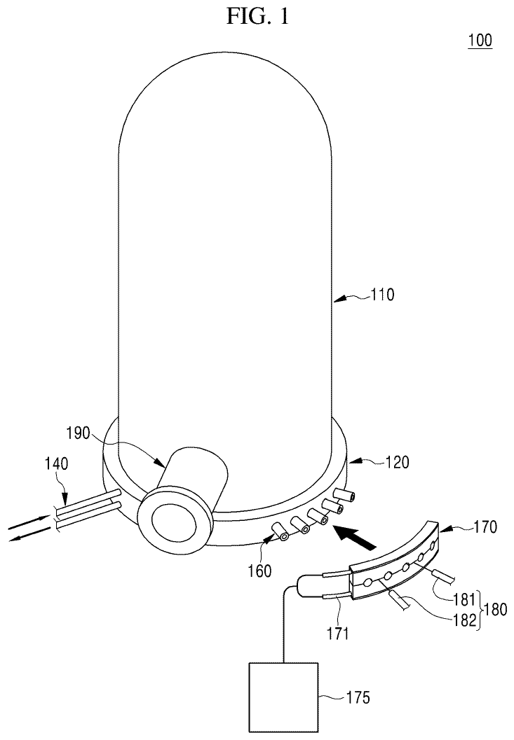

FIG. 1 is a schematic perspective view of a batch-type substrate-processing apparatus according to an embodiment of the present inventive concept.

Referring to FIG. 1, a batch-type substrate-processing apparatus 100 according to an embodiment of the present inventive concept may include: a reaction tube 110 providing a processing space in which a plurality of substrates are accommodated; a ring-shaped flange part 120 provided with fluid passages 121a and 121b and supporting the reaction tube 110; a first sealing member 131 provided between the reaction tube 110 and the flange part 120; a refrigerant-supply part 140 supplying a refrigerant to the fluid passages 121a and 121b; a gas-supply pipe 150 supplying a process gas to the processing space through the flange part 120; a gas inlet port 160 coupled to an outer end of the gas-supply pipe 150; and a heater part 170 heating the gas inlet port 160.

The reaction tube 110 may be made of a heat-resistant material such as quartz or ceramic in a cylindrical shape with a closed upper portion and an opened lower portion and may provide a processing space in which a plurality of substrates are accommodated to be processed therein. The processing space of the reaction tube 110 accommodates a substrate boat in which the plurality of substrates are laminated in a longitudinal direction of the reaction tube 110 and is a space in which an actual processing process (e.g., a deposition process) is performed.

Here, the substrate boat may be configured to support the substrates 10 and may be configured so that the plurality of substrates 10 are loaded in the longitudinal direction (i.e., upward and downward direction) of the process tube 110, and a plurality of unit processing spaces in which the plurality of substrates 10 are individually processed may be defined in the substrate boat.

The flange part 120 may be provided along a circumference of the reaction tube 110 in the shape of a ring at a lower end of the reaction tube 110 to support the reaction tube 110 and may be made of a metal such as stainless steel (SUS), and a first sealing member 131 such as an O-ring may be provided on a portion at which the flange part 120 and the reaction tube 110 are in contact with each other to prevent the process gas from leaking between the reaction tube 110 and the flange part 120. Here, the flange part 120 may form a concentric circle with the reaction tube 110.

Here, the fluid passage 121a and 121b may be provided in the flange part 120, and the refrigerant may flow into the fluid passage 121a and 121b to cool the first sealing member 131 that is in contact with the flange part 120, thereby preventing and/or suppressing thermal deformation and/or damage to the first sealing member 131. For example, the fluid passage 121a and 121b may be provided inside the flange part 120.

The first sealing member 131 may be provided between the reaction tube 110 and the flange part 120 to block a gap between the reaction tube 110 and the flange part 120, thereby preventing the process gas from leaking out of the processing space.

Here, the first sealing member 131 may be an O-ring or the like and may be provided in the ring shape along the circumference of the reaction tube 110. Since the substrate processing process may be performed at a high temperature of 600° C. or more, heat may be transferred from the reaction tube 110 due to the high process temperature (or treatment temperature) to cause deformation and/or damage.

The refrigerant-supply part 140 may supply the refrigerant such as cooling water to the fluid passages 121a and 121b and may allow the refrigerant to flow through the fluid passages 121a and 121b so that the first sealing member 131 is not deformed and/or damaged due to high temperature, and the refrigerant may cool the first sealing member 131 through heat-exchange with the first sealing member 131 through the flange part 120. Here, since the flange part 120 is made of a metal having excellent thermal conductivity, the heat-exchange between the refrigerant and the first sealing member 131 may be effectively performed, and thus, (rapid) heat-exchange between the first sealing member 131 and the flange part 120 due to excellent thermal conductivity and (rapid) heat-exchange between the flange part 120 and the refrigerant, (rapid) heat-exchange between the refrigerant and the first sealing member 131 may be substantially performed due to the excellent thermal conductivity, and the first sealing member 131 may be effectively cooled.

Here, the fluid passages 121a and 121b may extend along a circumferential direction of the flange part 120 and may be provided along the shape of the first sealing member 131 to effectively and evenly cool the first sealing member 131 as a whole. For example, when the first sealing member 131 has the ring shape, the fluid passages 121a and 121b may be provided so that the refrigerant is circulated along the circumferential direction of the flange part 120.

The gas-supply pipe 150 may supply a process gas to the processing space through the flange part 120 and may at least partially pass through the flange part 120. Here, one end (or inner end) of the gas-supply pipe 150 may face the inside of the reaction tube 110 and may be provided at the inside of the reaction tube 110, and the other end (or outer end) of the gas-supply pipe 150 may face the outside of the reaction tube 110 and may be provided at the outside of the reaction tube 110. Here, a nozzle (not shown) for injecting the process gas into the processing space may be provided at the inner end (or one end) of the gas-supply pipe 150, and a separate nozzle (not shown) may be connected (or coupled) to the inner end of the gas-supply pipe 150, or the inner end of the gas-supply pipe 150 may be provided as a nozzle (not shown).

For example, when the flange part 120 is provided at the lower portion of the reaction tube 110, the inner end of the gas-supply pipe 150 that passes through a sidewall of the flange part 120 in a radial direction toward the center of the flange part 120 may be bent to extend in the longitudinal direction (or upward direction) of the reaction tube 110 so as to be provided at the inside of the reaction tube 110, and when the flange part 120 is provided at the outside of the reaction tube 110, the inner end of the gas-supply pipe 150 that passes through the sidewall of the flange part 120 in the radial direction may also pass through the sidewall of the reaction tube 110 in the radial direction toward the center of the reaction tube 110 so as to be provided at the inside of the reaction tube 110. Here, the gas-supply pipe 150 may be made of a metal such as stainless steel (SUS), but the material of the gas-supply pipe 150 is not limited thereto and may vary.

The gas inlet port 160 may be coupled to the outer end (or other end) of the gas-supply pipe 150 and may be connected to a gas supply line (not shown) to introduce (inlet) the process gas supplied from a gas supply source (not shown) through the gas supply line (not shown) into the gas-supply pipe 150. Here, a heating means (not shown) such as a heating jacket may be provided in the gas supply line (not shown) to prevent condensation of the process gas, so that the process gas is supplied at a temperature (for example, 150° C. or more) at which the process gas is not condensed. Here, the gas inlet port 160 may be made of a metal such as stainless steel (SUS), and thus, a heat loss due to the refrigerant for cooling the first sealing member 131 may occur due to thermal influence from the flange part 120 by its excellent thermal conductivity.

For example, the gas inlet port 160 may be coupled to the outer end of the gas-supply pipe 150 to protrude (in the radial direction) outward from the reaction tube 110 and/or the flange part 120 and may also be in contact with the flange part 120. When the gas inlet port 160 is in contact with the flange part 120, the gas inlet port 160 may be thermally connected to the flange part 120, and thus, the heat of the gas inlet port 160 (i.e., the heat of the process gas in the gas inlet port) is (rapidly) conducted to the refrigerant flowing through the fluid passage 121a and 121b of the flange part 120 to cause the heat loss.

In this case, the process gas within the gas inlet port 160 may be condensed into powder and then accumulated on an inner surface of the gas inlet port 160, and the process gas may also be condensed to accumulate the powder at a coupled (or connected) portion between the gas inlet port 160 and the gas-supply pipe 150. As described above, the powder accumulated on the inner surface of the gas inlet port 160 and/or at the coupled portion of the gas inlet port 160 and the gas-supply pipe 150 may be supplied as particles to the processing space together with the process gas to cause a serious problem of deteriorating quality of a thin film formed (or deposited) through the substrate processing process.

The heater part 170 may heat the gas inlet port 160 and prevent the heat loss from occurring in the gas inlet port 160 due to the refrigerant flowing through the fluid passage 121a and 121b of the flange part 120 and prevent the process gas within the gas inlet port 160 from being condensed and changed into the powder due to the heat loss of the gas inlet port 160. As a result, the conventional problem in which the powder is accumulated on the inner surface of the gas inlet port 160 and/or the coupled portion of the gas inlet port 160 and the gas-supply pipe 150 and then supplied to the processing space together with the process gas to act as the particles, thereby deteriorating the quality of the thin film in the substrate processing space, may be solved. For example, the heater part 170 may be provided to surround the gas inlet port 160 to (uniformly) heat the gas inlet port 160 as a whole.

Thus, the batch-type substrate-processing apparatus 100 according to the present inventive concept may provide the fluid passage 121a and 121b in the flange part 120 to prevent the thermal deformation and/or the damage of the first sealing member 131 provided between the reaction tube 110 and the flange part 120 to sealing a space between the reaction tube 110 and the flange part 120, thereby heating the gas inlet port 160 through the heater part 170 while the refrigerant flows, and thus, the powder may be prevented from being accumulated on the inner surface of the gas inlet port 160 and the coupled portion of the gas inlet port 160 and the gas-supply pipe 150 due to the condensation (or heat loss) of the process gas caused by the heat loss of the gas inlet port 160. Thus, the serious problem of deteriorating the quality of the thin film, in which the powder is supplied together with the process gas to the processing space to act as the particles in the substrate processing process, may be solved.

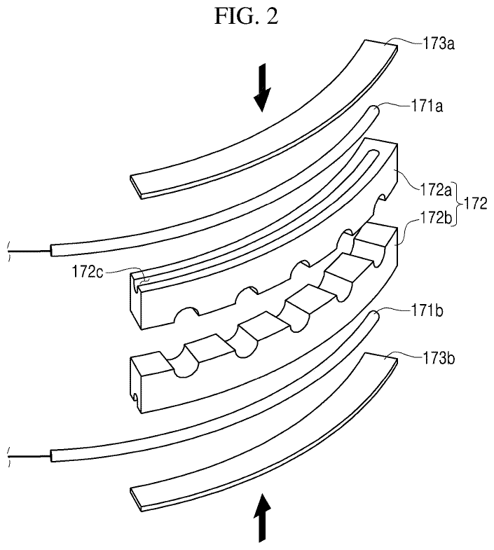

FIG. 2 is an exploded perspective view of the heater part according to an embodiment of the present inventive concept.

Referring to FIG. 2, the heater part 170 may include a line heater 171 extending along the circumferential direction of the flange part 120; and a metal block 172 in which the line heater 171 is built and provided to surround the gas inlet port 160. The line heater 171 may extend along the circumferential direction of the flange part 120 and may be provided parallel to (or in parallel with) the fluid passage 121a and 121b. For example, the line heater 171 may have a curved line shape along the circumferential direction of the ring-shaped flange part 120. In this case, the fluid passage 121a and 121b through which the refrigerant flows and the line heater 171 may face each other, and thus, the gas inlet port 160 affected by the refrigerant flowing through the fluid passage 121a and 121b may be uniformly heated in the circumferential direction of the flange part 120, and linear cooling (or line cooling) by the refrigerant flowing along the fluid passage 121a and 121b may be (thermally) offset through the linear heating (or line heating) of the line heater 171 at the gas inlet port 160.

In addition, the line heater 171 may be disposed parallel to the first sealing member 131, and thus, the heat from the line heater 171 may be evenly distributed without being concentrated on a portion of the first sealing member 131, and the line heater 171 may be disposed further from the first sealing member 131 than the fluid passage 121a and 121b, and thus, the thermal influence of the line heater 171 on the first sealing member 131 may be minimized (or prevented).

The metal block 172 may be provided to surround the gas inlet port 160, may be provided with the line heater 171 therein, may extend along an extension direction of the line heater 171, and may conduct heat of the line heater 171. That is, the metal block 172 may effectively and evenly the heat the gas inlet port 160 through heat conduction and may surround the gas inlet port 160 to uniformly heat the entire area. For example, the metal block 172 may be at least partially made of aluminum (Al), and heat of the line heater 171 may be rapidly transferred (or conducted) through the high thermal conductivity of aluminum (Al) to effectively heat the gas inlet port 160.

Here, the metal block 172 may include an upper block 172a covering an upper portion of the gas inlet port 160; and a lower block 172b covering a lower portion of the gas inlet port 160. The upper block 172a may cover the upper portion of the gas inlet port 160, the lower block 172b may cover the lower portion of the gas inlet port 160, and the upper block 172a and the lower block 172b may surround the gas inlet port 160 from above and below.

For example, the upper block 172a and the lower block 172b may be formed symmetrically (vertically) and may be coupled to and separated from each other. The upper block 172a and the lower block 172b may be coupled to meet each other from above and below with the gas inlet port 160 therebetween to surround the gas inlet port 160 and may also be separated from each other for maintenance, etc. Here, a coupling groove may be defined along the circumference of the gas inlet port 160 so that the gas inlet port 160 is at least partially inserted into and coupled to the upper block 172a and the lower block 172b. Here, a circumference of an upper (half) portion of the gas inlet port 160 may be inserted into the coupling groove of the upper block 172a, and a circumference of a lower (half) portion of the gas inlet port 160 may be inserted into the coupling groove of the lower block 172b.

In the case in which the metal block 172 is constituted by the upper block 172a and the lower block 172b, an installation of the heater part 170 (i.e., an installation of the metal block) to the gas inlet port 160 may be facilitated, and in the case in which a plurality of gas-supply pipes 150 are respectively disposed along the circumference of the flange part 120 in the radial direction by passing through the flange part 120 in the radial direction, a plurality of gas inlet ports 160 respectively coupled to the plurality of gas-supply pipes 150 may be surrounded (or covered) at the same time, and the plurality of gas inlet ports 160 may be heated together (integrally) at the same time. As a result, the plurality of gas inlet ports 160 may be uniformly heated, and the plurality of gas inlet ports 160 may be effectively heated even with a minimum number (for example, one or two) of line heaters 171.

In the case in which the metal block 172 is constituted by a left block and a right block to surround the gas inlet port 160 at both sides thereof, it is not only difficult to embed the line heater 171 extending along the circumferential direction of the flange part 120, but also, when attempting to surround the plurality of gas inlet ports 160, which are respectively coupled to the plurality of gas-supply pipes 150 disposed along the circumferential direction of the flange part 120, by passing through the flange part 120 in the radial direction, the plurality of gas inlet ports 160 may not be surrounded all at once, and when attempting to surround the plurality of gas inlet ports 160 all at once, the plurality of gas inlet ports 160 may not be surrounded individually. However, the upper block 172a and the lower block 172b may surround the plurality of gas inlet ports 160 at the same time while respectively surrounding the plurality of gas inlet ports 160.

In addition, when the metal block 172 is constituted by a front block and a rear block to surround the gas inlet port 160 from the front and rear, the gas inlet port 160 has to pass through both the front block and the rear block, and thus, it is difficult for the front block and the rear block to be in contact with (or be in close contact with) the gas inlet port 160, and the front block and the rear block may not be formed symmetrically because distances from the flange part 120 are different. However, the upper block 172a and the lower block 172b may be provided in a (vertically) symmetrical manner by surrounding the gas inlet port 160 from above and below and being in close contact with (or in contact with) the gas inlet port 160.

Here, the line heater 171 may include an upper heater 171a provided on the upper block 172a; and a lower heater 171b provided on the lower block 172b. The upper block 172a and the lower block 172b may be provided symmetrically (vertically), and thus, the upper heater 171a may be symmetrically provided to the upper block 172a, and the lower heater 171b may be symmetrically provided to the lower block 172b. The upper heater 171a and the lower heater 171b may be disposed symmetrically at the same distance from the gas inlet port 160 and may be configured in the same number.

For example, one upper heater 171a may be disposed in a curved shape in the upper block 172a, and one lower heater 171b may be disposed in a curved shape in the lower block 172b. The upper heater 171a and the lower heater 171b may be parallel to each other and symmetrical with respect to the gas inlet port 160. The gas inlet port 160 may be heated evenly and effectively through the upper heater 171a and the lower heater 171b, and even when the plurality of gas inlet ports 160 are heated at the same time, the plurality of gas inlet ports 160 may be heated effectively and evenly.

In addition, the upper block 172a and the lower block 172b may include heater insertion grooves 172c into which the upper heater 171a and the lower heater 171b are inserted, respectively, and the metal block 172 may further include an upper block cover 173a and a lower block cover 173b that cover the heater insertion grooves 172c of the upper block 172a and the lower block 172b, respectively. The heater insertion groove 172c may be defined in the upper block 172a and the lower block 172b, and the upper heater 171a may be inserted into the heater insertion groove 172c of the upper block 172a, and the lower heater 171b may be inserted into the heater insertion groove 172c of the lower block 172b. As a result, even when each of the upper heater 171a and the lower heater 171b has a curved shape, the upper heater 171a may be simply and easily embedded in the upper block 172a, and the lower heater 171b may be embedded in the lower block 172b. The upper block 172a and the lower block 172b may be in contact with the upper heater 171a and the lower heater 171b, respectively, as well as the gas inlet port 160 and thus may be made of aluminum (Al) to effectively transfer (or conduct) the heat of the upper heater 171a and the lower heater 171b to the gas inlet port 160 through high thermal conductivity.

Here, since the metal block 172 further includes the upper block cover 173a and the lower block cover 173b, the upper block cover 173a may cover the heater insertion groove 172c of the upper block 172a so that the upper heater 171a is embedded in the metal block 172 (i.e., in the upper block), and the lower heater 171b is embedded in the metal block 172 (i.e., in the lower block) so that the heater insertion groove 172c of the lower block cover 173b covers the heater insertion groove 172c. The upper block cover 173a and the lower block cover 173b may prevent the upper heater 171a and the lower heater 171b from being separated by covering the heater insertion grooves 172c of the upper block 172a and the lower block 172b after the upper heater 171a and the lower heater 171b are inserted into the heater insertion grooves 172c of the upper block 172a and the lower block 172b, respectively, and may play a role in protecting the upper heater 171a and the lower heater 171b.

For example, each of the upper block cover 173a and the lower block cover 173b may be made of aluminum (Al) for close coupling (or contact) with the upper block 172a and the lower block 172b, but are not limited thereto, and may be made of an insulating material to prevent the heat of the upper heater 171a and the lower heater 171b from being dissipated to the outside (or to an opposite side of the gas inlet port).

Thus, the batch-type substrate-processing apparatus 100 according to the present inventive concept may be provided to surround the gas inlet port 160 because the heater part 170 is constituted by the line heater 171 extending along the circumferential direction of the flange part 120 and the metal block 172 in which the line heater 171 is embedded, thereby preventing the heat loss from the gas inlet port 160 and maintaining an internal temperature of the gas inlet port 160 to a temperature at which the process gas is not condensed.

The batch-type substrate-processing apparatus 100 according to the present inventive concept may further include a temperature detection part 180 that detects the temperature of the heater part 170; and a heating control part 175 that controls the heating temperature of the heater part 170 according to the temperature detected by the temperature detection part 180.

The temperature detection part 180 may detect the temperature of the heater part 170 (e.g., the temperature of the line heater), and the (internal) temperature of the gas inlet port 160 may be known through the detected temperature of the heater part 170. Here, the heating temperature of the heater part 170 may be a (heating) temperature set in the heating control part 175.

The heating control part 175 may control the heating temperature of the heater part 170 according to the temperature detected by the temperature detection part 180 and adjust the heating temperature of the heater part 170 according to the detected temperature of the heater part 170 (i.e., the identified (internal) temperature of the gas inlet port 160) to maintain the internal temperature of the gas inlet port 160 to a temperature (e.g., 150° C. to 170° C.) at which the process gas is not condensed.

Thus, power (or fuel) consumption for the heat generation (or heating) of the heater part 170 may be reduced (or minimized) without affecting the cooling of the first sealing member 131 through the flange part 120 by the heating of the heater part 170.

The gas-supply pipe 150 may be provided in plurality and may pass through the flange part 120 in the radial direction (or thickness direction), and the plurality of gas-supply pipes 150 may be disposed along the circumferential direction of the flange part 120. The gas-supply pipe 150 may be provided in plurality, and each of the plurality of gas-supply pipes 150 may pass through the flange part 120 in the radial direction, and the plurality of gas-supply pipes 150 may be disposed along the circumferential direction of the flange part 120 in parallel in the radial direction. The gas inlet port 160 may be coupled to an outer end of each of the plurality of gas-supply pipes 150, and a different gas may be supplied to each of the gas-supply pipes 150, or the same gas may be supplied to the gas-supply pipes 150. Here, the plurality of gas inlet ports 160 which are respectively coupled to the plurality of gas-supply pipes 150 may be heated by the heater part 170 to prevent the condensation of the (process) gas.

Here, a length of the line heater 171 may be proportional to the number of gas-supply pipes 150, and may become longer as the number of gas-supply pipes 150 increases. That is, the length of the line heater 171 may be proportional to the number of gas inlet ports 160, which increases to the same number as the number of gas-supply pipes 150, and the line heater 171 may heat the plurality of gas inlet ports 160 at the same time. As a result, the plurality of gas inlet ports 160 may be uniformly heated regardless of the number of gas-supply pipes 150 (i.e., the number of gas inlet ports).

Thus, in the batch-type substrate-processing apparatus 100 according to the present inventive concept, the heater part 170 may be configured to be in proportion to the number of gas-supply pipes 150 even when the gas-supply pipes 150 are provided in plurality and also may allow the internal temperature of the plurality of gas inlet ports 160 to be uniform through the line heater 171 extending along the circumferential direction of the flange part 120 and may maintain the internal temperature of each gas inlet port 160 to the temperature at which the process gas is not condensed.

Here, the temperature detection part 180 may include a first temperature measurement member 181 provided at a central portion of the line heater 171 in the extension direction of the heater part 170; and a second temperature measurement member 182 provided at an edge portion of the line heater 171 in the extension direction of the heater part 170 and spaced apart from the first temperature measurement member 181 in the extension direction of the line heater 171. The first temperature measurement member 181 may be provided at the central portion of the line heater 171 in the extension direction of the heater part 170 to measure a first temperature of the heater part 170, and the first temperature of the heater part 170 may be a representative temperature of the heater part 170 (or a representative temperature similarly measured in several portions).

The second temperature measurement member 182 may be spaced apart from the first temperature measurement member 181 in the extension direction of the line heater 171 and may be provided at the edge portion of the line heater 171 in the extension direction of the heater part 170 to measure the second temperature of the heater part 170, and the second temperature of the heater part 170 may be a specific temperature of the heater part 170 (or a special temperature that appears only at a specific portion). Here, the second temperature measurement member 182 may be provided in plurality and may be symmetrically disposed at both sides of the first temperature measurement member 181, but since the temperature characteristics are symmetrically displayed according to the extension direction position of the line heater 171, (only) one second temperature measurement member 182 may be disposed at either side of the first temperature measurement member 181.

For example, the first temperature measurement member 181 and the second temperature measurement member 182 may be thermocouples (T/C), but are not limited thereto, and the temperature of the heater member 170 (i.e., the first temperature and the second temperature) may be measured in various manners.

The heating control part 175 may control the heating temperature of the heater part 170 based on the first temperature of the heater part 170 measured from the first temperature measurement member 181 and may control the heating temperature of the heater part 170 by reflecting the second temperature of the heater part 170 based on a difference between the first temperature of the heater part 170 and the second temperature of the heater part 170 measured from the second temperature measurement member 182. The heating control part 175 may control the heating temperature of the heater part 170 based on the first temperature of the heater part 170 measured from the first temperature measurement member 181 and may control the heating temperature of the heater part 170 based on the first temperature of the heater part 170, which is a representative temperature of the heater part 170. Since the representative temperature of the heater part 170 is measured at most positions (or portions), it may be considered as an actual temperature of the heater part 170, and the heating temperature of the heater part 170 may be controlled based on the first temperature of the heater part 170.

In addition, the heating control part 175 may reflect the second temperature of the heater part 170 in the heating temperature control of the heater part 170 according to the difference between the second temperature of the heater part 170 measured by the second temperature measurement member 182 and the first temperature of the heater part 170. If the difference between the first temperature of the heater part 170 and the second temperature of the heater part 170 is not so great and thus is ignored, the second temperature of the heater part 170 may not be reflected. If the difference between the first temperature of the heater part 170 and the second temperature of the heater part 170 is so great so that the specific temperature of the heater part 170 has an effect, the heating temperature of the heater part 170 may be controlled by reflecting the second temperature of the heater part 170. Since the specific temperature of the heater part 170 is measured only at a small number of specific positions (or portions), the heating temperature of the heater part 170 may be controlled by reflecting the second temperature of the heater part 170 to the first temperature of the heater part 170 according to the difference between the first temperature of the heater part 170 and the second temperature of the heater part 170.

For example, the heating temperature of the heater part 170 to be changed may be primarily determined based on the first temperature of the heater part 170, and the heating temperature of the heater part 170 to be changed may be auxiliarily corrected by reflecting the second temperature of the heater part 170 according to the size of the difference between the first temperature of the heater part 170 and the second temperature of the heater part 170.

Here, the heating control part 175 may reflect the second temperature of the heater part 170 when the difference between the first temperature of the heater part 170 and the second temperature of the heater part 170 is greater than an allowable value. If the difference between the first temperature of the heater part 170 and the second temperature of the heater part 170 is less than or equal to the second temperature, the second temperature (or the specific temperature) of the heater part 170 may be at a negligible level, and thus, the heating control part 175 may control the heating temperature of the heater part 170 (only) based on the first temperature of the heater part 170 without reflecting the second temperature of the heater part 170. In addition, when the difference between the first temperature of the heater part 170 and the second temperature of the heater part 170 is greater than the allowable value, the second temperature (or the specific temperature) of the heater part 170 may have an effect to partially cause a temperature (or portion) lower than the temperature at which the process gas is not condensed, and thus, the heating control part 175 may control the heating temperature of the heater part 170 by reflecting the second temperature of the heater part 170 (to the first temperature of the heater part). That is, when the difference between the first temperature of the heater part 170 and the second temperature of the heater part 170 is large, the second temperature of the heater part 170 may be reflected in the heating temperature control of the heater part 170, and the heating temperature of the heater part 170 may be auxiliarily corrected by reflecting the second temperature of the heater part 170 to the heating temperature of the heater part 170 that is primarily determined based on the first temperature of the heater part 170.

An interval (in the circumferential direction of the flange part) between the first temperature measurement member 181 and the second temperature measurement member 182 may be greater than that (in the circumferential direction of the flange part) of the plurality of gas-supply pipes 150. Here, the plurality of gas-supply pipes 150 may be disposed at equal intervals in the circumferential direction of the flange part 120. Since the specific temperature of the heater part 170 is (mainly) generated at both ends of the line heater 171 in the extension direction, if the interval between the first temperature measurement member 181 and the second temperature measurement member 182 is set to be less than that between the plurality of gas-supply pipes 150, the second temperature measurement member 182 may not measure the specific temperature of the heater part 170, and the specific temperature of the heater part 170 may not be reflected in the heating temperature control of the heater part 170. In addition, the second temperature of the heater part 170 measured from the second temperature measurement member 182 that measures the representative temperature of the heater part 170 rather than the specific temperature of the heater part 170 may not be different greatly from the first temperature of the heater part 170, and thus, even the second temperature of the heater part 170 may not be reflected in the heating temperature control of the heater part 170.

However, the interval between the first temperature measurement member 181 and the second temperature measurement member 182 may be larger than that between the plurality of gas-supply pipes 150, the second temperature measurement member 182 may measure a temperature at one of both ends of the line heater 171 in the extension direction and may measure the specific temperature of the heater part 170, and thus, the specific temperature of the heater part 170 may be reflected in the heating temperature control of the heater part 170.

Thus, the batch-type substrate-processing apparatus 100 according to the present inventive concept may detect the temperature of the heater part 170 through the temperature detection part 180 to control the heating temperature of the heater part 170, thereby controlling the gas inlet port 160 to a desired temperature. In addition, the temperature detection part 180 may be constituted by the first temperature measurement member 181 provided at the central portion of the line heater 171 in the extension direction of the heater part 170 and the second temperature measurement member 182 provided at the edge portion of the extension direction of the line heater 171, and thus, the heating temperature of the heater part 170 may be controlled based on the first temperature of the heater part 170 measured from the first temperature measurement member 181, and the second temperature of the heater part 170 may be reflected according to the difference between the second temperature of the heater part 170 measured from the second temperature measurement member 182 and the first temperature of the heater part 170 to control the plurality of gas inlet ports 160 to a uniform temperature.

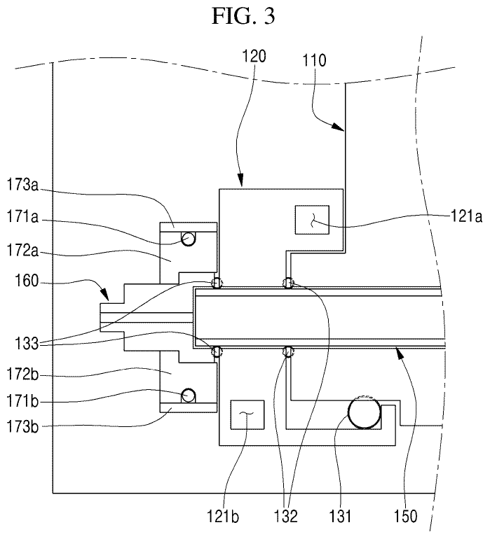

FIG. 3 is a conceptual view for explaining a coupling structure of the gas inlet port and the heater part according to an embodiment of the present inventive concept.

Referring to FIG. 3, the gas-supply pipe 150 may pass through the reaction tube 110 in the radial direction and supply the process gas to the processing space within the reaction tube 110. Here, the flange part 120 may be provided at the outside of the reaction tube 110, and thus, the inner end of the gas-supply pipe 150 may pass through both a sidewall of the flange part 120 and a sidewall of the reaction tube 110 toward the center of the reaction tube 110 in the radial direction.

The batch-type substrate-processing apparatus 100 according to the present inventive concept may further include a second sealing member 132 provided between the reaction tube 110 and the gas-supply pipe 150; and a third sealing member 133 provided between the gas-supply pipe 150 and the gas inlet port 160.

The second sealing member 132 may be provided between the reaction tube 110 and the gas-supply pipe 150 to seal a space between the reaction tube 110 and the gas-supply pipe 150 and block the space between the reaction tube 110 and the gas-supply pipe 150, thereby preventing the process gas from leaking between the reaction tube 110 and the gas-supply pipe 150.

For example, the second sealing member 132 may be an O-ring or the like and may be provided in a ring shape around the gas-supply pipe 150. The second sealing member 132 may also be deformed and/or damaged due to the high process temperature.

The third sealing member 133 may be provided between the gas-supply pipe 150 and the gas inlet port 160 to seal the space between the gas-supply pipe 150 and the gas inlet port 160 and block the space between the gas-supply pipe 150 and the gas inlet port 160, thereby preventing the process gas from leaking between the gas-supply pipe 150 and the gas inlet port 160.

For example, the third sealing member 133 may also be an O-ring, etc., and may be provided in a ring shape around the gas-supply pipe 150. The third sealing member 133 may also be deformed and/or damaged due to the high process temperature.

The flange part 120 may be provided outside a lower end of the reaction tube 110, and the gas-supply pipe 150 may extend further through the flange part 120 in the radial direction to the reaction tube 110 to pass through (both) the flange part 120 and the reaction tube 110. That is, the flange part 120 may be provided outside the lower end of the reaction tube 110, and also, the gas-supply pipe 150 may pass through both the sidewall of the flange part 120 and the sidewall of the reaction tube 110 toward the center of the reaction tube 110 in the radial direction, and an inner end of the gas-supply pipe 150 may be provided inside the reaction tube 110.

For example, the reaction tube 110 may have a protrusion that protrudes outward (or in the radial direction) along the circumference of the reaction tube 110 at the lower end, the flange part 120 may be provided to surround the protrusion at the outside of the protrusion of the reaction tube 110, and the gas-supply pipe 150 may pass through the sidewall of the flange part 120 in the radial direction to the protrusion, and thus, the inner end may be provided inside the reaction tube 110 through the protrusion. Here, the flange part 120 may be constituted by a lower flange and an upper fixing ring. The lower flange may support the reaction tube 110 at the lower portion of the reaction tube 110 (i.e., the lower portion of the protrusion), and the upper fixing ring may press the protrusion from an upper side to allow the reaction tube 110 and the lower flange (i.e., the protrusion and the lower flange) to be in close contact with the first sealing member 131. As a result, the space between the reaction tube 110 and the lower flange may be sealed (or sealed).

Here, the plurality of fluid passages 121a and 121b may be provided in the flange part 120. Here, one fluid passage 121b may be provided for cooling the first sealing member 131, and the other fluid passage 121a may be provided for cooling the second sealing member 132 and the third sealing member 133. Here, one of the fluid passages 121b may cool the second sealing member 132 and the third sealing member 133, and the other fluid passage 121a may cool the first sealing member 131. In addition, one fluid passage 121a may be provided in the upper fixing ring, and the other fluid passage 121b may be provided in the lower flange. The refrigerant may be introduced through one fluid passage 121a and discharged through the other fluid passage 121b.

Here, the second sealing member 132 may be disposed between the reaction tube 110 and the flange part 120 and be interposed between the gas-supply pipe 150 and the reaction tube 110 and the flange part 120, and the third sealing member 133 may be disposed between the gas-supply pipe 150 and the flange part 120 and be interposed between the gas inlet port 160 and the gas-supply pipe 150 and the flange part 120. The second sealing member 132 may be interposed between the gas-supply pipe 150 and the reaction tube 110 to prevent the process gas from leaking between the reaction tube 110 and the gas-supply pipe 150, and may also be interposed between the gas-supply pipe 150 and the flange part 120 to prevent the direct contact between the gas-supply pipe 150 and the flange part 120, thereby suppressing or preventing the heat loss of the gas-supply pipe 150 due to the refrigerant flowing in the fluid passage 121a and 121b of the flange part 120.

The third sealing member 133 may be interposed between the gas inlet port 160 and the gas-supply pipe 150 to prevent the process gas from leaking between the gas-supply pipe 150 and the gas inlet port 160 and may also be interposed between the gas-supply pipe 150 and the flange part 120 to effectively prevent the direct contact between the gas-supply pipe 150 and the flange part 120, thereby effectively suppressing or preventing the heat loss of the gas-supply pipe 150 due to the refrigerant flowing through the fluid passage 121a and 121b of the flange part 120.

In addition, the second sealing member 132 and the third sealing member 133 may doubly seal (or seal) not only between the reaction tube 110 and the gas-supply pipe 150, but also between the flange part 120 and the gas-supply pipe 150 to effectively prevent the process gas from leaking (or discharged) to the outside by leaking out between the reaction tube 110 and the gas-supply pipe 150 and/or between the flange part 120 and the gas-supply pipe 150 from the processing space.

Here, the heater part 170 may be provided outside the flange part 120. Since the first sealing member 131, the second sealing member 132, and the third sealing member 133 are provided (or disposed) at an inner side (and/or inside) of the flange part 120, the heater part 170 may be provided at the outside of the flange part 120 so as not to have a thermal effect on the first sealing member 131, the second sealing member 132, and the third sealing member 133 and may be disposed further away from the first sealing member 131, the second sealing member 132, and the third sealing member 133 than the fluid passages 121a and 121b. In addition, the heater part 170 may effectively heat the gas inlet port 160 by surrounding the gas inlet port 160 at the outside of the flange part 120 and being in close contact with (or adhering to) the gas inlet port 160. Here, the heater part 170 may be in contact with the outside of the flange part 120 or may be spaced from the flange part 120, but it may be preferable to be spaced from the flange part 120 while being in contact with the gas inlet port 160 so as to effectively heat the gas inlet port 160 without being thermally affected by the flange part 120. The third sealing member 133 may also be interposed between the gas inlet port 160 and the flange part 120 to separate the gas inlet port 160 from the flange part 120, thereby suppressing (or minimizing) the heat loss in the gas-supply pipe 150 due to the refrigerant flowing through the fluid passage 121a and 121b of the flange part 120.

An inner diameter of the gas inlet port 160 may be less than an inner diameter of the gas-supply pipe 150. When the inner diameter of the gas inlet port 160 is small, the process gas inside the gas inlet port 160 may be effectively heated by heating the gas inlet port 160, and since the inner pressure of the gas inlet port 160 is relatively high, the process gas may be diffused into the inside of the gas-supply pipe 150 with a larger inner diameter and a relatively lower pressure to quickly passes through a portion (or section) corresponding to the flange part 120 of the gas-supply pipe 150, thereby preventing the condensation of the process gas inside the gas-supply pipe 150 and preventing the powder from being accumulated on the inner surface of the gas-supply pipe 150 due to the condensation of the process gas. Here, a portion corresponding to the flange part 120 of the gas-supply pipe 150 may be a portion (section) of an outer end of the gas-supply pipe 150. Since the inner diameter of the gas-supply pipe 150 is large, the process gas quickly passing through the gas-supply pipe 150 may be prevented and/or suppressed from being in contact with the inner surface of the gas-supply pipe 150 to prevent and/or suppress the condensation of the process gas and/or the accumulation of the powder on the inner surface of the gas-supply pipe 150.

The batch-type substrate-processing apparatus 100 of the present inventive concept may further include an exhaust part 190 for exhausting the inside of the reaction tube 110.

The exhaust part 190 may exhaust the inside of the reaction tube 110 and may serve to exhaust process residues within the processing space to the outside. The exhaust part 190 may be constituted by an exhaust nozzle extending in the longitudinal direction of the reaction tube 110, an exhaust line connected to the exhaust nozzle, an exhaust port, and an exhaust pump. The exhaust nozzle may be provided with a plurality of exhaust holes arranged in a vertical direction to respectively correspond to unit processing spaces of the substrate boat.

Here, the process gas may include one or more gases and may include a source gas and a reaction gas that reacts with the source gas to generate a thin film material. For example, when the thin film material to be deposited on the substrate is silicon nitride, the source gas may include a gas containing silicon, such as dichlorosilane (SiH₂Cl₂, abbreviated as DCS), and the reaction gas may include a gas containing nitrogen, such as NH₃, N₂O, or NO.

The batch-type substrate-processing apparatus 100 of the present inventive concept may further include a heating cover (not shown) surrounding the reaction tube 110 to heat the plurality of the substrates. In addition, the substrate boat may rotate by a rotation means connected to a lower portion of the substrate boat to ensure uniformity of the processing.

As described above, according to the present inventive concept, the fluid passage may be provided in the flange part to prevent the thermal deformation and/or damage of the first sealing member provided between the reaction tube and the flange part, thereby heating the gas inlet port through the heater part while the refrigerant flows, and thus, the powder may be prevented and/or suppressed from being accumulated at the inner circumferential surfaces of the gas-supply pipe and the gas inlet port and the coupled portion of the gas-supply pipe and the gas inlet port due to the concentration of the process gas. Here, the heater part may be constituted by the line heater extending along the circumferential direction of the flange part and the metal block, in which the line heater is built, to maintain an internal temperature of each of the gas inlet port and/or the gas-supply pipe to a temperature at which the process gas is not condensed. In addition, even when the gas-supply pipe is provided as a plurality of parts, the heater part nay be provided in proportion to the number of gas-supply pipes, and the internal temperature of each gas-supply pipe and the gas inlet port may be uniformly maintained to a temperature at which the process gas is not condensed through the heater part extending along a circumferential direction of the flange part. Here, the temperature of the heater part is detected through a temperature detection part, and a heating temperature of the heater part is controlled to control the gas inlet port to a desired temperature. In addition, the temperature detection part may be constituted by the first temperature measurement member provided at the central portion in the extension direction of the line heater of the heater part and the second temperature measurement member provided at the edge portion in the extension direction of the line heater to control the plurality of gas inlet ports to the uniform temperature by reflecting the second temperature of the heater part according to the difference between the second temperature of the heater part, which is measured from the second temperature measurement member, and the first temperature of the heater part while controlling the heating temperature of the heater part on the basis of the first temperature of the heater part, which is measured from the first temperature measurement member.

Although preferred embodiments of the present inventive concept have been described with reference to a number of illustrative embodiments thereof, the embodiments of the present inventive concept are not limited to the foregoing embodiments, and thus, it should be understood that numerous other modifications and embodiments may be devised by those skilled in the art that will fall within the spirit and scope of the principles of this disclosure. Hence, the real protective scope of the present inventive concept shall be determined by the technical scope of the accompanying claims.

1. A batch-type substrate-processing apparatus comprising:
a reaction tube configured to provide a processing space in which a plurality of substrates are accommodated;
a ring-shaped flange part provided with a fluid passage and configured to support the reaction tube;
a first sealing member provided between the reaction tube and the flange part;
a refrigerant-supply part configured to supply a refrigerant to the fluid passage;
a gas-supply pipe configured to supply a process gas to the processing space through the flange part;
a gas inlet port coupled to an outer end of the gas-supply pipe; and
a heater part configured to heat the gas inlet port.

2. The batch-type substrate-processing apparatus of claim 1, wherein the heater part comprises:
a line heater extending along a circumferential direction of the flange part; and
a metal block embedded in the line heater and provided to surround the gas inlet port.

3. The batch-type substrate-processing apparatus of claim 2, wherein the metal block comprises:
an upper block configured to cover an upper portion of the gas inlet port; and
a lower block configured to cover a lower portion of the gas inlet port.

4. The batch-type substrate-processing apparatus of claim 3, wherein the line heater comprises:
an upper heater provided in the upper block; and
a lower heater provided in the lower block,
wherein the upper block and the lower block comprise heater insertion grooves into which the upper heater and the lower heater are inserted, respectively, and
the metal block further comprises an upper block cover and a lower block cover, which are configured to cover the heater insertion grooves of the upper block and the lower block, respectively.

5. The batch-type substrate-processing apparatus of claim 2, further comprising:
a temperature detection part configured to detect a temperature of the heater part; and
a heating control part configured to control a heating temperature of the heater part according to the temperature detected by the temperature detection part.

6. The batch-type substrate-processing apparatus of claim 4, wherein the gas-supply pipe is provided in plurality and passes through the flange part in a radial direction,
wherein the plurality of gas-supply pipes are disposed along a circumferential direction of the flange part, and
a length of the line heater is proportional to the number of gas-supply pipes.

7. The batch-type substrate-processing apparatus of claim 6, wherein the temperature detection part comprises:
a first temperature measurement member provided at a central portion of the heater part in an extension direction of the line heater; and
a second temperature measurement member spaced apart from the first temperature measurement member in the extension direction of the line heater and provided at an edge portion of the heater part in the extension direction of the line heater.

8. The batch-type substrate-processing apparatus of claim 7, wherein the heating control part is configured to:
control the heating temperature of the heater part based on a first temperature of the heater part, which is measured from the first temperature measurement member; and
control the heating temperature of the heater part by reflecting a second temperature of the heater part according to a difference between the first temperature of the heater part and the second temperature of the heater part, which is measured from the second temperature measurement member.

9. The batch-type substrate-processing apparatus of claim 8, wherein the heating control part is configured to reflect the second temperature of the heater part when the difference between the first temperature of the heater part and the second temperature of the heater part is greater than an allowable value.

10. The batch-type substrate-processing apparatus of claim 7, wherein an interval between the first temperature measurement member and the second temperature measurement member is greater than that between the plurality of gas-supply pipes.

11. The batch-type substrate-processing apparatus of claim 1, wherein the gas-supply pipe passes through the reaction tube in a radial direction, and
the batch-type substrate-processing apparatus further comprises:
a second sealing member provided between the reaction tube and the gas-supply pipe; and
a third sealing member provided between the gas-supply pipe and the gas inlet port.

12. The batch-type substrate-processing apparatus of claim 11, wherein the flange part is provided outside a lower end of the reaction tube,
the gas-supply pipe further passes through the flange part in the radial direction,
the second sealing member is disposed between the reaction tube and the flange part,
the third sealing member is disposed between the gas-supply pipe and the flange part, and
the heater part is provided outside the flange part.

13. The batch-type substrate-processing apparatus of claim 12, wherein an inner diameter of the gas inlet port is less than an inner diameter of the gas-supply pipe.
